(19) United States
(12) Patent Application Publication
(10) Pub. No.: US 2024/0055438 A1
(43) Pub. Date: Feb. 15, 2024

(54) METHOD OF MANUFACTURING ARRAY SUBSTRATE, ARRAY SUBSTRATE, AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Chuanbao Luo, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/440,186

(22) PCT Filed: Aug. 3, 2021
(86) PCT No.: PCT/CN2021/110289

§ 371 Date: Sep. 17, 2021

(30) Foreign Application Priority Data
Jul. 27, 2021 (CN) 202110849094.X

(51) Int. Cl. H01L 27/12; H01L 25/16

(52) U.S. Cl. CPC H01L 27/124; H01L 27/1288; H01L 25/167

(57) ABSTRACT

The present application discloses a method of manufacturing an array substrate, an array substrate, and a display panel. The present application saves one photolithography process by patterning a first metal layer, a buffer layer, and a semiconductor layer in a same manufacturing process, and also saves one photolithography process by manufacturing a third electrode plate, a drain electrode, a gate electrode, a source electrode, and a connection portion in a same manufacturing process. Therefore, the method of manufacturing the array substrate provided by the present application can reduce two photolithography processes, which is beneficial to improve a production efficiency of the array substrate.

### FIELD OF INVENTION

The present application relates to a field of display technology and more particularly to a method of manufacturing an array substrate, an array substrate, and a display panel.

### BACKGROUND OF INVENTION

At present, mini/micro light emitting diode (mLED) display technology has entered a stage of accelerated development, and mLEDs can be applied to small and medium-sized displays. Compared with organic light emitting diode (OLED) displays, mLED displays show a better performance in terms of cost, contrast, a high brightness, and thin profiles. In the mLED display technology, an array substrate technology as a key technology controls the mLED displays. However, current manufacturing methods of the array substrate used to control the mLED displays are complicated.

### SUMMARY OF INVENTION

The present application provides a method of manufacturing an array substrate, an array substrate, and a display panel.

The present application provides a method of manufacturing an array substrate, including:

providing a substrate;

providing a first metal layer, a buffer layer, and a semiconductor layer on the substrate sequentially, and patterning the first metal layer, the buffer layer, and the semiconductor layer, wherein the first metal layer forms a first electrode plate, a first light shielding portion and a first metal portion, the buffer layer forms a first buffer portion, a second buffer portion, and a third buffer portion, the semiconductor layer forms a second electrode plate and an active portion, and wherein the first electrode plate, the first buffer portion and the second electrode plate are disposed correspondingly, the first light shielding portion, the second buffer portion and the active portion are disposed correspondingly, and the third buffer portion is positioned at a side of the first metal portion away from the substrate; and

providing a second metal layer on a side of the semiconductor layer away from the substrate and patterning the second metal layer to form a third electrode plate, a drain electrode, a gate electrode, a source electrode, and a connecting portion, wherein the connecting portion is connected to the first metal portion.

In some embodiments, after the step of providing the first metal layer, the buffer layer, and the semiconductor layer on the substrate sequentially, and patterning the first metal layer, the buffer layer, and the semiconductor layer, the method further includes:

providing a gate insulating layer covering the first metal layer, the buffer layer, and the semiconductor layer, and patterning the gate insulating layer to form a first opening, a second opening, a third opening, and a fourth opening, wherein the first opening and the second opening expose the active portion, the third opening exposes the first light shielding part, and the fourth opening exposes the first metal portion.

In some embodiments, after the step of providing the second metal layer on the side of the semiconductor layer away from the substrate, and patterning the second metal layer to form the third electrode plate, the drain electrode, the gate electrode, the source electrode, and the connecting portion, the method further includes:

providing a first passivation layer covering the second metal layer and patterning the first passivation layer to form a first opening and a second opening, wherein the first opening exposes the source, and the second opening exposes the connecting portion.

In some embodiments, after the step of providing the first passivation layer covering the second metal layer, and patterning the first passivation layer to form the first opening and the second opening, the method further includes:

providing a protective layer in the second opening.

In some embodiments, after the step of providing the protective layer in the second opening, the method further includes:

providing a second passivation layer and a second light shielding portion on a side of the first passivation layer away from the second metal layer sequentially.

In some embodiments, after the step of providing the second passivation layer and the second light shielding portion on the side of the first passivation layer away from the second metal layer sequentially, the method further includes:

providing a light emitting diode in the first opening.

In some embodiments, the step of providing a first metal layer, a buffer layer, and a semiconductor layer on the substrate sequentially and patterning the first metal layer, the buffer layer, and the semiconductor layer includes:

providing the first metal layer, the buffer layer, the semiconductor layer, and the photoresist layer on the substrate sequentially;

exposing the photoresist layer through a half-tone photomask or a grayscale photomask; and

patterning the first metal layer, the buffer layer, and the semiconductor layer.

The present application further provides an array substrate, wherein the array substrate is manufactured by a method of manufacturing the array substrate, and wherein the array substrate includes:

a substrate;

a first metal layer, a buffer layer, and a semiconductor layer provided on the substrate sequentially, wherein the first metal layer includes a first electrode plate, a first light shielding portion and a first metal portion, the buffer layer includes a first buffer portion, a second buffer portion, and a third buffer portion, the semiconductor layer includes a second electrode plate and an active portion, and wherein the first electrode plate, the first buffer portion and the second electrode plate are disposed correspondingly, the first light shielding portion, the second buffer portion, and the active portion are disposed correspondingly, and the third buffer portion is positioned at a side of the first metal portion away from the substrate; and

a second metal layer provided on a side of the semiconductor layer away from the substrate, wherein the second metal layer includes a third electrode plate, a drain electrode, a gate electrode, a source electrode, and a connecting portion, and wherein the connecting portion is connected to the first metal portion.

In some embodiments, the second metal layer is a three-layer metal structure of indium zinc oxide/molybdenum/copper or a double-layer metal structure of molybdenum oxide/copper.

In some embodiments, a thickness of the indium zinc oxide layer ranges from 15 to 30 nanometers, and a thickness of the molybdenum oxide layer ranges from 20 to 30 nanometers.

In some embodiments, the array substrate further includes a first passivation layer covering the second metal layer, wherein the first passivation layer includes a first opening and a second opening, and wherein the first opening exposes the source electrode, and the second opening exposes the connecting portion.

In some embodiments, a light emitting diode is provided in the first opening, wherein the light emitting diode is connected to the source electrode, wherein a protective layer is provided in the second opening, and wherein the protective layer covers the connecting portion.

In some embodiments, the array substrate further includes a second passivation layer and a second light shielding portion, wherein the second passivation layer is provided on a side of the first passivation layer away from the second metal layer, and wherein the second light shielding portion is provided on a side of the second passivation layer away from the first passivation layer.

The present application further provides a display panel, including an array substrate, wherein the array substrate includes:

a substrate;

a first metal layer, a buffer layer, and a semiconductor layer provided on the substrate sequentially, wherein the first metal layer includes a first electrode plate, a first light shielding portion and a first metal portion, the buffer layer includes a first buffer portion, a second buffer portion, and a third buffer portion, the semiconductor layer includes a second electrode plate and an active portion, and wherein the first electrode plate, the first buffer portion and the second electrode plate are disposed correspondingly, the first light shielding portion, the second buffer portion, and the active portion are disposed correspondingly, and the third buffer portion is positioned at a side of the first metal portion away from the substrate; and

a second metal layer provided on a side of the semiconductor layer away from the substrate, and the second metal layer includes a third electrode plate, a drain electrode, a gate electrode, a source electrode, and a connecting portion, and wherein the connecting portion is connected to the first metal portion.

In some embodiments, the second metal layer is a three-layer metal structure of indium zinc oxide/molybdenum/copper or a double-layer metal structure of molybdenum oxide/copper.

In some embodiments, a thickness of the indium zinc oxide layer ranges from 15 to 30 nanometers, and a thickness of the molybdenum oxide layer ranges from 20 to 30 nanometers.

In some embodiments, the array substrate further includes a first passivation layer covering the second metal layer, and the first passivation layer includes a first opening and a second opening, and wherein the first opening exposes the source electrode, and the second opening exposes the connecting portion.

In some embodiments, a light emitting diode is provided in the first opening, wherein light emitting diode is connected to the source electrode, wherein a protective layer is provided in the second opening, and wherein the protective layer covers the connecting portion.

In some embodiments, the array substrate further includes a second passivation layer and a second light shielding portion, wherein the second passivation layer is provided on a side of the first passivation layer away from the second metal layer, and wherein the second light shielding portion is provided on a side of the second passivation layer away from the first passivation layer.

The present application discloses a method of manufacturing an array substrate, an array substrate, and a display panel. The method of manufacturing the array substrate saves one photolithography process by patterning the first metal layer, the buffer layer, and the semiconductor layer in a same manufacturing process, and also saves one photolithography process and manufactures the third electrode plate, the drain electrode, the gate electrode, the source electrode, and the connection portion in a same manufacturing process by patterning the second metal layer. Therefore, the method of manufacturing the array substrate provided by the present application can reduce two photolithography processes, and the manufacturing method is simple, which is beneficial to improve a production efficiency of the array substrate.

### DESCRIPTION OF FIGURES

In order to explain the technical solutions in the present application more clearly, the following will briefly introduce the figures used in the description of the embodiments. Obviously, the figures in the following description are only some embodiments of the present application. For those skilled in the art, without inventive steps, other figures can be obtained from these figures.

FIG. 1 is a flowchart of a first embodiment of a method of manufacturing an array substrate provided by the present application.

FIG. 2 is a flowchart of a second embodiment of the method of manufacturing the array substrate provided by the present application.

FIG. 3a to FIG. 3i are schematic diagrams of a second embodiment of the method of manufacturing the array substrate provided by the present application.

FIG. 4 is a schematic structural diagram of a first embodiment of the array substrate provided by the present application.

FIG. 5 is a schematic structural diagram of a second embodiment of the array substrate provided by the present application.

FIG. 6 is a schematic structural diagram of a display panel provided by one embodiment of the present application.

### DETAILED DESCRIPTION OF EMBODIMENTS

The technical solutions in the embodiments of the present application will be clearly and completely described below in conjunction with the figures in the embodiments of the present application. Obviously, the described embodiments are only a part of the embodiments of the present application, rather than all the embodiments. Based on the embodiments in the present application, all other embodiments obtained by those skilled in the art without inventive steps shall fall within the protection scope of the present application.

The technical solutions in the embodiments of the present application will be clearly and completely described below in conjunction with the figures in the embodiments of the present application. It should be noted that in the embodiments of the present invention, it should be understood that terms such as “including” or “having” are intended to indicate the features, numbers, steps, behaviors, components, parts or combinations thereof disclosed in this specification, and it is not intended to exclude a possibility of one or more other features, numbers, steps, behaviors, components, parts or combinations or additions thereof. In the various embodiments of the present invention, it should be understood that the value of a sequence number of the following processes does not mean an order of execution, and the order of execution of each process should be determined by its function and internal logic. The implementation process of the embodiments of the present invention should not constitute any limitation.

The embodiment of the present application provides a method of manufacturing an array substrate, and the present application will be described in detail below with reference to specific embodiments.

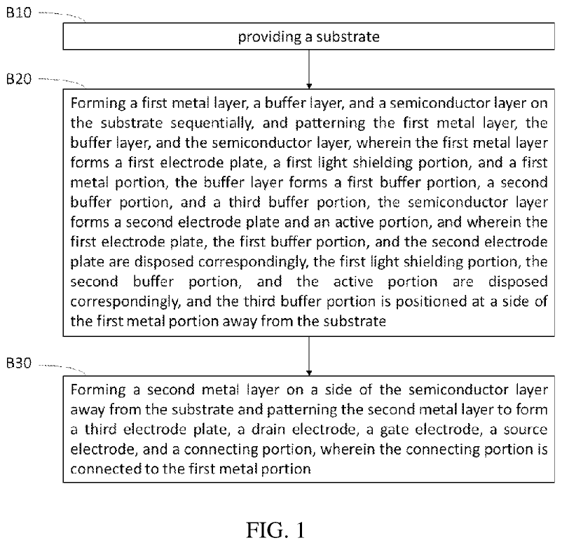

Please refer to FIG. 1. FIG. 1 is a flowchart of a first embodiment of a method of manufacturing an array substrate provided by the present application.

Step B10: Providing a substrate.

The substrate may be a glass substrate or a flexible substrate. The present application does not limit the substrate here.

Step B20: Forming a first metal layer, a buffer layer, and a semiconductor layer on the substrate sequentially, and patterning the first metal layer, the buffer layer, and the semiconductor layer. The first metal layer forms a first electrode plate, a first light shielding portion and a first metal portion. The buffer layer forms a first buffer portion, a second buffer portion, and a third buffer portion. The semiconductor layer forms a second electrode plate and an active portion. The first electrode plate, the first buffer portion and the second electrode plate are disposed correspondingly. The first light shielding portion, the second buffer portion and the active portion are disposed correspondingly, and the third buffer portion is positioned at a side of the first metal portion away from the substrate.

The first metal layer may be formed of molybdenum (Mo) or a laminated metal of molybdenum (Mo)/copper (Cu). The first metal layer can be formed by physical vapor deposition. The buffer layer may be formed of a silicon oxide (SiOₓ) or a stack of a silicon oxide (SiOₓ)/a silicon nitride (SiNₓ). The buffer layer can be formed by chemical vapor deposition. The semiconductor layer 13 may be formed of one or more of a gallium indium zinc oxide (IGZO), a gallium zinc indium tin oxide (IGZTO), or a gallium indium tin oxide (IGTO).

Step B30: Forming a second metal layer on a side of the semiconductor layer away from the substrate and patterning the second metal layer to form a third electrode plate, a drain electrode, a gate electrode, a source electrode, and a connecting portion. The connecting portion is connected to the first metal portion.

In some embodiments, the second metal layer may be formed of a three-layer metal structure of indium zinc oxide (IZO)/molybdenum (Mo)/copper (Cu) or a double-layer metal of molybdenum oxide (MoOx)/copper (Cu). A method of forming the second metal layer is the same as a method of forming the first metal layer, and will not be repeated here.

The method of manufacturing the array substrate saves one photolithography process by patterning the first metal layer, the buffer layer, and the semiconductor layer in a same manufacturing process, and also saves one photolithography process and manufactures the third electrode plate, the drain electrode, the gate electrode, the source electrode, and the connection portion in a same manufacturing process by patterning the second metal layer. Therefore, the method of manufacturing the array substrate provided by the present application can reduce two photolithography processes, and the manufacturing method is simple, which is beneficial to improve a production efficiency of the array substrate.

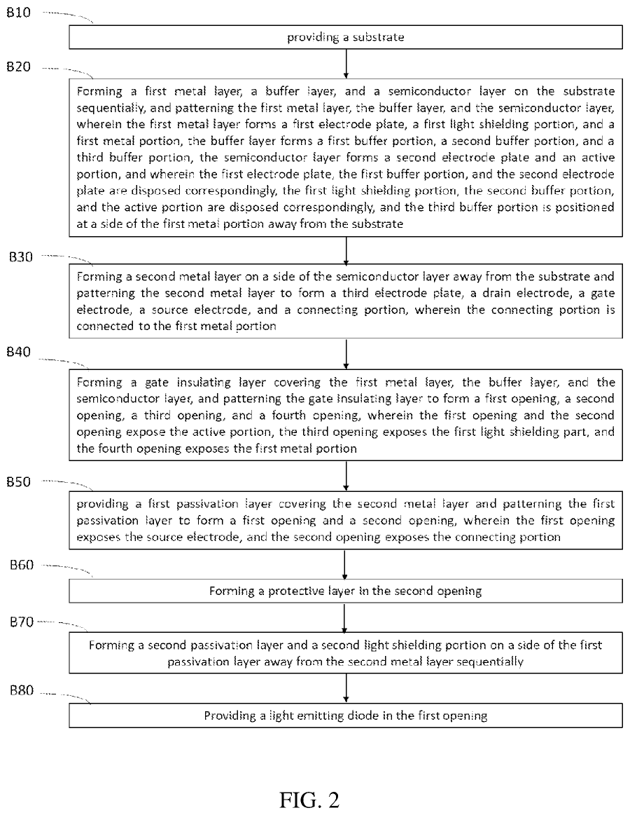

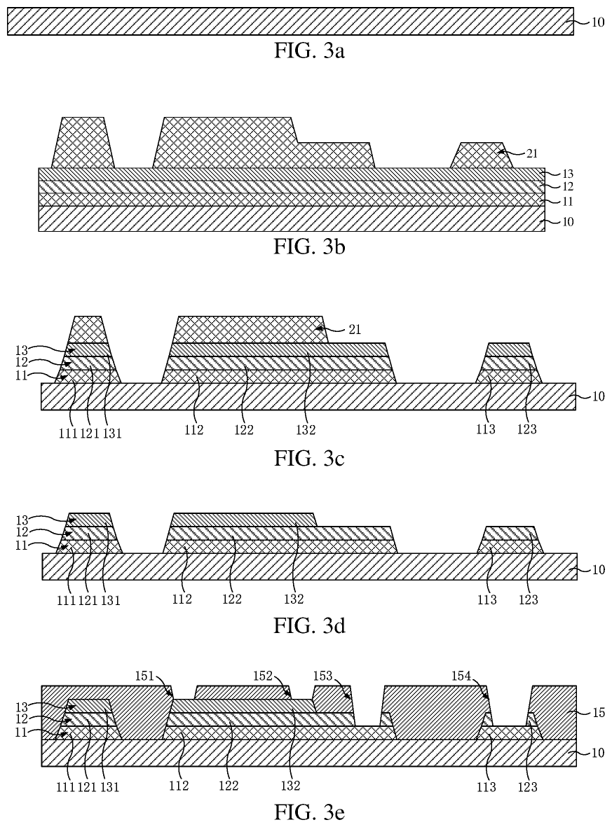

Please refer to FIG. 2 and FIGS. 3a to 3i. FIG. 2 is a flowchart of a second embodiment of the method of manufacturing the array substrate provided by the present application. FIG. 3a to FIG. 3i are schematic diagrams of a second embodiment of the method of manufacturing the array substrate provided by the present application.

The present application also provides the flowchart of the second embodiment of the method of manufacturing the array substrate.

Step B10: Providing a substrate.

As shown in FIG. 3a, the substrate 10 may be a glass substrate or a flexible substrate. The present application does not limit the substrate 10 here.

Step B20: Forming a first metal layer, a buffer layer, and a semiconductor layer on the substrate sequentially, and patterning the first metal layer, the buffer layer, and the semiconductor layer. The first metal layer forms a first electrode plate, a first light shielding portion, and a first metal portion. The buffer layer forms a first buffer portion, a second buffer portion, and a third buffer portion. The semiconductor layer forms a second electrode plate and an active portion. The first electrode plate, the first buffer portion, and the second electrode plate are disposed correspondingly. The first light shielding portion, the second buffer portion, and the active portion are disposed correspondingly, and the third buffer portion is positioned at a side of the first metal portion away from the substrate.

Materials and methods of forming the first metal layer, the buffer layer, and the semiconductor layer are the same as materials and methods of forming the first metal layer, the buffer layer, and the semiconductor layer in the first embodiment, and will not be repeated here.

In some embodiments, the step of forming the first metal layer, the buffer layer, and the semiconductor layer on the substrate sequentially, and patterning the first metal layer, the buffer layer, and the semiconductor layer includes:

Step B21: Forming the first metal layer, the buffer layer, the semiconductor layer, and the photoresist layer on the substrate sequentially.

As shown in FIG. 3b, the first metal layer 11, the buffer layer 12, the semiconductor layer 13, and the photoresist layer 21 are sequentially formed on the substrate 10.

The materials and methods of providing the first metal layer 11, the buffer layer 12, and the semiconductor layer 13 are the same as those in the first embodiment of the method of manufacturing the array substrate provided in the present application, and will not be repeated here.

In some embodiments, after the step of forming the buffer layer, it may further include:

Performing a thermal annealing (TA) treatment on the buffer layer.

The thermal annealing treatment can reduce a stress of the buffer layer 12, thereby reducing an occurrence of a strain, and reducing an occurrence of film peeling, thereby improving a stability of the array substrate 100.

Step B22: Exposing the photoresist layer through a half-tone photomask or a gray-scale mask.

A half tone mask (HTM) or a gray tone mask (GTM) includes: a translucent region, an opaque region, and a fully transparent region. The translucent region is configured to reduce a thickness of the photoresist layer at a corresponding position. The photoresist layer at a corresponding position is completely removed by using the fully transparent region, and the photoresist layer at a corresponding position of the opaque region will be all retained. It can be understood that, according to a difference in positive and negative properties of a photoresist, the positions corresponding to the opaque region and the fully transparent region can be interchanged. As shown in FIG. 3b, the HTM or the GTM is configured to expose the photoresist layer 21 to completely remove the photoresist layer 21 in regions other than thin film transistors, capacitors and data lines to be formed, and at the same time form the photoresist layer 21 with two thicknesses.

Step B23: patterning the first metal layer, the buffer layer, and the semiconductor layer.

As shown in FIG. 3c, the photoresist layer 21 is used for shielding, and the first metal layer 11, the buffer layer 12, and the semiconductor layer 13 are etched, wherein a film layer not covered by the photoresist layer 21 is etched and removed. Specifically, the first metal layer 11 is etched by wet etching. The first metal layer 11 forms a first electrode plate 111, a first light shielding portion 112, and a first metal portion 113. The buffer layer 12 is etched by dry etching. The buffer layer 12 forms a first buffer portion 121, a second buffer portion 122, and a third buffer portion 123. The semiconductor layer 13 is etched by wet etching. The semiconductor layer 13 forms a second electrode plate 131 and a first electrode plate 111 of the active portion 132. The first buffer part 121 and the second electrode plate 131 are arranged correspondingly. The first light shielding portion 112, the second buffer portion 122, and the active portion 132 are arranged correspondingly. The third buffer portion 123 is positioned on a side of the first metal portion 113 away from the substrate 10.

In some embodiments, after the step of patterning the first metal layer, the buffer layer, and the semiconductor layer, the method may further include:

Step B24: Ashing the photoresist layer.

As shown in FIG. 3c, specifically, the photoresist layer 21 is ashed by dry ashing, wherein a thinner photoresist layer 21 is ashed and removed, and a thicker photoresist layer 21 is thinned. Dry ashing can be performed by means of local heating, laser irradiation, or oxygen plasma ashing (Oxygen plasma ashing).

In some embodiments, after the step of ashing the photoresist layer, the method may further include:

Step B25: Performing a second patterning process on the semiconductor layer.

As shown in FIG. 3d, the photoresist layer 21 remaining after the ashing process is used for shielding, and the semiconductor layer 13 is patterned. Specifically, the semiconductor layer 13 is etched by wet etching.

In some embodiments, after the step of performing the second patterning process on the semiconductor layer, the method further includes:

Step B26: Peeling off the photoresist layer.

As shown in FIG. 3d, the photoresist layer 21 is peeled off.

Step B40: Forming a gate insulating layer covering the first metal layer, the buffer layer, and the semiconductor layer, and patterning the gate insulating layer to form a first opening, a second opening, a third opening, and a fourth opening. The first opening and the second opening expose the active portion. The third opening exposes the first light shielding part, and the fourth opening exposes the first metal portion.

As shown in FIG. 3e, forming the gate insulating layer 15 covering the first metal layer 11, the buffer layer 12, and the semiconductor layer 13, and patterning the gate insulating layer 15 to form a first opening 151, a second opening 152, a third opening 153, and a fourth opening 154. The first opening 151 and the second opening 152 expose the semiconductor layer 13. The third opening 153 exposes the first light shielding portion 112. The fourth opening 154 exposes the first metal portion 113. The gate insulating layer 15 may be formed by chemical vapor deposition. The gate insulating layer 15 may be formed of a stack of SiOₓ or SiOₓ/SiNₓ.

In some embodiments, the first opening 151 and the second opening 152 are plasma treated to form a channel region and a non-channel region of the thin film transistor.

By performing the plasma treatment to the first opening 151 and the second opening 152, a conductorization of the active portion 132 corresponding to the plasma treatment of the first opening 151 and the second opening 152 can be achieved. A conductorized region of the active portion 132 can be used as a channel region of the thin film transistor. A region where the active portion 132 is not conductorized can be used as a non-channel region of the thin film transistor.

Step B30: Forming a second metal layer on a side of the semiconductor layer away from the substrate and patterning the second metal layer to form a third electrode plate, a drain electrode, a gate electrode, a source electrode, and a connecting portion, wherein the connecting portion is connected to the first metal portion.

As shown in FIG. 3f, specifically, providing a second metal layer 14 on a side of the gate insulating layer 15 away from the substrate 10. The second metal layer 14 is patterned to form the third electrode plate 141, the drain electrode 142, the gate electrode 143, the source electrode 144, and the connecting portion 145. The connection portion 145 is connected to the first metal portion 113. The source electrode 144 is positioned in the second opening 152 and the third opening 153. The source electrode 144 is connected to the active portion 132 and the first light shielding portion 112. Specifically, the source electrode 144 is connected to the channel region of the active portion 132. The drain electrode 142 is positioned in the first opening 151. The drain electrode 142 is connected to the active portion 132. Specifically, the drain electrode 142 is connected to the channel region of the active portion 132. The connecting portion 145 is positioned in the fourth opening 154. The connection portion 145 is connected to the first metal portion 113. The second metal layer 14 may be formed by physical vapor deposition.

The first electrode plate 111, the first buffer portion 121, and the second electrode plate 131 constitute a first capacitor. The second electrode plate 131, the gate insulating layer 15, and the third electrode plate 141 constitute a second capacitor. The first capacitor and the second capacitor are connected in parallel. In the present application, by sharing the second electrode plate 131 with the first capacitor and the second capacitor, it is possible to achieve a larger charge storage capacity in a smaller space, thereby improving a performance of the array substrate 100.

Materials and methods of manufacturing the second metal layer 14 are the same as materials and methods of forming the second metal layer of the first embodiment of the method of manufacturing the array substrate provided in the present application, and will not be repeated here.

Step B50: providing a first passivation layer covering the second metal layer and patterning the first passivation layer to form a first opening and a second opening. The first opening exposes the source electrode, and the second opening exposes the connecting portion.

As shown in FIG. 3g, the first passivation layer 16 covering the second metal layer 14 is formed. The first passivation layer 16 is patterned to form the first opening 161 and the second opening 162. The first opening 161 exposes the source electrode 144. The second opening 162 exposes the connection portion 145. The first passivation layer 16 may be formed by chemical vapor deposition. The first passivation layer 16 may be formed of a stack of SiOₓ or SiOₓ/SiNₓ.

Step B60: Forming a protective layer in the second opening.

As shown in FIG. 3h, the protective layer 17 is formed in the second opening 162. The protective layer 17 may be formed by physical vapor deposition. The protective layer 17 may be formed of a metal oxide such as ITO or IZO. A thickness of the protective layer 17 ranges from 50 nanometers to 100 nanometers. Specifically, the thickness of the protective layer 17 may be 50 nanometers, 60 nanometers, 70 nanometers, 80 nanometers, 90 nanometers, or 100 nanometers.

In the present application, by providing the protective layer 17 on the connecting portion 145, the connecting portion 145 can be prevented from being corroded by external water vapor, and the connecting portion 145 can also be prevented from being thermally oxidized due to a high temperature in a subsequent manufacturing process, resulting in poor connections. In addition, due to good film-forming properties of ITO and IZO, by providing the protective layer 17 on the connecting portion 145, a flatness of the connecting portion 145 can also be improved, thereby improving reliability of the connections.

Step B70: Forming a second passivation layer and a second light shielding portion on a side of the first passivation layer away from the second metal layer sequentially.

As shown in FIG. 3i, the second passivation layer 18 and the second light shielding portion 19 are sequentially formed on a side of the first passivation layer 16 away from the second metal layer 14. The second passivation layer 18 may be formed by chemical vapor deposition. The second passivation layer 18 may be formed of a stack of SiOₓ or SiOₓ/SiNₓ. The second light shielding portion 19 may be formed by chemical vapor deposition. The second light shielding portion 19 may be formed of a photoresist material with high light shielding.

In the present application, by providing the second passivation layer 18 between the second light shielding portion 19 and the first passivation layer 16, it is possible to prevent a high temperature from affecting the second metal layer 14 when the second light shielding portion 19 is formed. In addition, in the present application, by providing the second light shielding portion 19, an influence of external light on the thin film transistor can be blocked, thereby improving a stability of the array substrate 100.

Step B80: Providing a light emitting diode in the first opening.

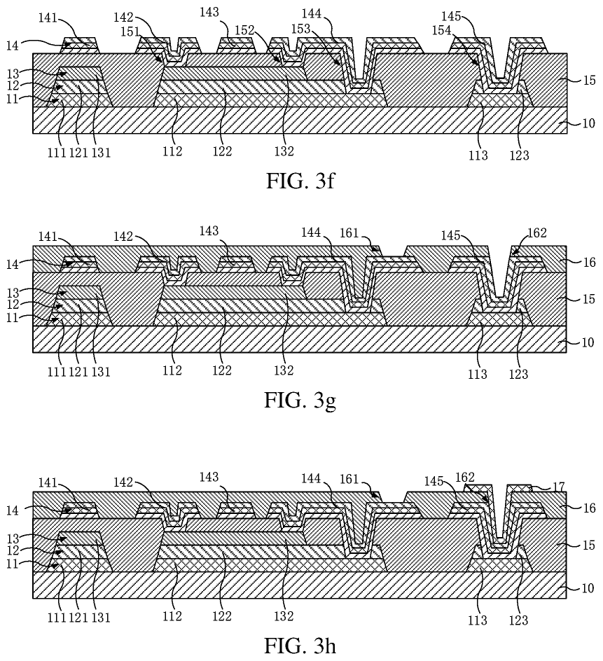

As shown in FIG. 4, the light emitting diode 20 is provided in the first opening 161. The light emitting diode 20 may be one of mini LEDs or micro LEDs.

In some embodiments, before providing the light emitting diode 20 in the first opening 161, the method may further include: bonding a solder paste printing and an anisotropic conductive adhesive (ACF).

The method of manufacturing the array substrate saves one photolithography process by patterning the first metal layer, the buffer layer, and the semiconductor layer in a same manufacturing process, and also saves one photolithography process and manufactures the third electrode plate, the drain electrode, the gate electrode, the source electrode, and the connection portion in a same manufacturing process by patterning the second metal layer. Therefore, the method of manufacturing the array substrate provided by the present application can reduce two photolithography processes, and the manufacturing method is simple, which is beneficial to improve a production efficiency of the array substrate.

Please refer to FIG. 4, FIG. 4 is a schematic structural diagram of a first embodiment of the array substrate provided by the present application.

The present application provides an array substrate 100. The array substrate 100 includes a substrate 10, a first metal layer 11, a buffer layer 12, a semiconductor layer 13, and a second metal layer 14. The first metal layer 11, the buffer layer 12, and the semiconductor layer 13 are stacked on the substrate 10 in sequence. The second metal layer 14 is disposed on a side of the semiconductor layer 13 away from the substrate 10. The first metal layer 11 includes a first electrode plate 111, a first light shielding portion 112, and a first metal portion 113. The buffer layer 12 includes a first buffer portion 121, a second buffer portion 122, and a third buffer portion 123. The semiconductor layer 13 includes a second electrode plate 131 and an active portion 132. The first electrode plate 111, the first buffer portion 121, and the second electrode plate 131 are disposed correspondingly. The first light shielding portion 112, the second buffer portion 122, and the active portion 132 are disposed correspondingly. The third buffer portion 123 is positioned on a side of the first metal portion 113 away from the substrate 10. The second metal layer 14 includes a third electrode plate 141, a drain electrode 142, a gate electrode 143, a source electrode 144, and a connection portion 145. The connection part 145 is connected to the first metal portion 113.

The array substrate provided in the present application includes a substrate 10, a first metal layer 11, a buffer layer 12, a semiconductor layer 13, and a second metal layer 14. The present application saves one photolithography process by patterning the first metal layer 11, the buffer layer 12, and the semiconductor layer 13 in a same manufacturing process, and also saves one photolithography process and manufactures the third electrode plate 141, the drain electrode 142, the gate electrode 143, the source electrode 144, and the connection portion 145 in a same manufacturing process by patterning the second metal layer 14. Therefore, the array substrate 100 provided by the present application can reduce two photolithography processes during a manufacturing process, and the manufacturing process is simple, which is beneficial to improve a production efficiency of the array substrate 100.

The second metal layer 14 is a three-layer metal structure of IZO/Mo/Cu, wherein the IZO layer 14a serves as a low-reflection functional layer, Cu serves as an electrode layer. By providing Mo between the IZO layer 14a and Cu, an adhesion between the IZO layer 14a and Cu can be improved. A thickness of the IZO layer 14a ranges from 15 to 30 nanometers. Specifically, the thickness of the IZO layer 14a may be 15 nanometers, 20 nanometers, 25 nanometers, or 30 nanometers.

In some embodiments, the array substrate 100 further includes a gate insulating layer 15. The gate insulating layer 15 covers the first metal layer 11, the buffer layer 12, and the semiconductor layer 13.

The gate insulating layer 15 may be formed of a stack of SiOₓ or SiOₓ/SiNₓ.

In some embodiments, the array substrate 100 further includes a first passivation layer 16. The first passivation layer 16 covers the second metal layer 14. The first passivation layer 16 includes a first opening 161 and a second opening 162. The first opening 161 exposes the source electrode 144. The second opening 162 exposes the connection portion 145.

In some embodiments, a protective layer 17 is provided in the second opening 162. The protective layer 17 covers the connection portion 145.

The protective layer 17 may be formed of a metal oxide such as ITO or IZO. The protective layer 17 may be formed by physical vapor deposition. A thickness of the protective layer 17 ranges from 50 nanometers to 100 nanometers. Specifically, the thickness of the protective layer 17 may be 50 nanometers, 60 nanometers, 70 nanometers, 80 nanometers, 90 nanometers, or 100 nanometers.

In the present application, by providing the protective layer 17 on the connecting portion 145, the connecting portion 145 can be prevented from being corroded by external water vapor, and the connecting portion 145 can also be prevented from being thermally oxidized due to a high temperature in a subsequent manufacturing process, resulting in poor connections. In addition, due to good film-forming properties of ITO and IZO, by providing the protective layer 17 on the connecting portion 145, a flatness of the connecting portion 145 can also be improved, thereby improving a reliability of the connections.

In some embodiments, the light emitting diode 20 is provided in the first opening 161. The light emitting diode 20 is connected to the source electrode 144.

The light emitting diode 20 may be one of mini LEDs or micro LEDs.

In some embodiments, the array substrate 100 further includes a second passivation layer 18 and a second light shielding portion 19. The second passivation layer 18 is disposed on a side of the first passivation layer 16 away from the second metal layer 14. The second light shielding portion 19 is disposed on a side of the second passivation layer 18 away from the first passivation layer 16.

The second passivation layer 18 may be formed of a stack of SiOₓ or SiOₓ/SiNₓ. The second passivation layer 18 may be formed by chemical vapor deposition. The second light shielding portion 19 may be formed of a photoresist material with high light shielding. The second light shielding portion 19 may be configured to be a light shielding layer of the channel region of the thin film transistor.

In the present application, by providing the second passivation layer 18 between the second light shielding portion 19 and the first passivation layer 16, it is possible to prevent a high temperature from affecting the second metal layer 14 when the second light shielding portion 19 is formed. In addition, in the present application, by providing the second light shielding portion 19, an influence of external light on the thin film transistor can be blocked, thereby improving a stability of the array substrate 100.

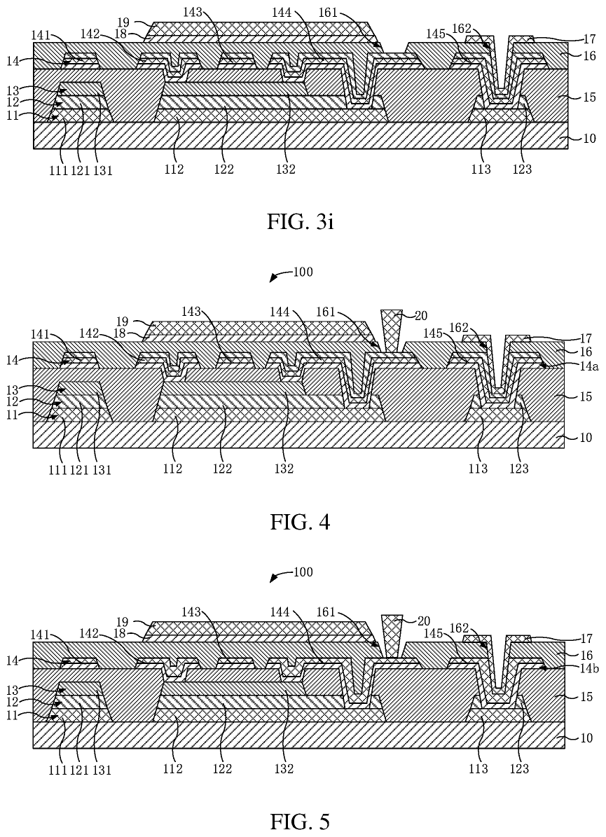

Please refer to FIG. 5. FIG. 5 is a schematic structural diagram of a second embodiment of the array substrate provided by the present application.

A difference between the array substrate provided by the second embodiment and the array substrate provided by the first embodiment is:

The second metal layer 14 is a double-layer metal structure of MoOx/Cu.

The MoOx layer 14b is configured to be a low-reflection functional layer. Cu layer is configured to be an electrode layer. A thickness of the MoOx layer 14b ranges from 20 nm to 30 nm. Specifically, the thickness of the MoOx layer 14b may be 20 nanometers, 25 nanometers, or 30 nanometers.

In the present application, the second metal layer 14 is configured to be a three-layer metal structure of IZO/Mo/Cu or a double-layer metal structure of MoOx/Cu. The IZO layer 14a and the MoOx layer 14b are configured to be low-reflection functional layers, which can reduce a reflection of scattered light passing through a drain electrode 142, a gate electrode 143, and a source electrode 144 and entering into the active portion 132 and affect a stability of the array substrate 100.

In the present application, a thickness of the IZO layer 14a ranges from 15 nanometers to 30 nanometers, and a thickness of the MoOx layer 14b ranges from 20 to 30 nanometers, which facilitates removal of the IZO layer 14a and the MoOx layer 14b in a corresponding region to pattern the second metal layer 14.

Other structures of the array substrate provided by the second embodiment are the same as structures of the array substrate provided by the first embodiment, and will not be repeated here.

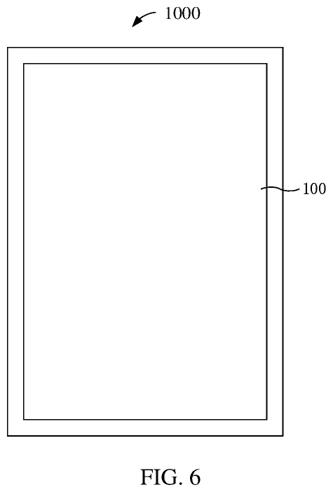

Please refer to FIG. 6, FIG. 6 is a schematic structural diagram of a display panel provided by one embodiment of the present application.

The display panel 1000 includes the array substrate 100 as described in any of previous embodiments.

The display panel 1000 provided in the present application includes an array substrate 100. The array substrate includes a substrate, a first metal layer, a buffer layer, a semiconductor layer, and a second metal layer. By patterning the first metal layer, the buffer layer, and the semiconductor layer in a same manufacturing process, one photolithography process is saved. By patterning the second metal layer, the third electrode plate, the drain electrode, the gate electrode, the source electrode, and the connection portion are manufactured in a same manufacturing process, and a photolithography process is also saved. Two photolithography processes in manufacturing the display panel 1000 and the array substrate 100 provided in the present application can be reduce, and the manufacturing method is simple, which is beneficial to improve a production efficiency of the array substrate 100 and the display panel 1000.

In summary, although the detailed description of the embodiments of the present application is as above, the foregoing embodiments are not intended to limit the present application. Those of ordinary skill in the art should understand that they can still modify the technical solutions described in the foregoing embodiments, or equivalently replace some of the technical features; and these modifications or replacements do not make the essence of the corresponding technical solutions deviate from a scope of the technical solutions of the embodiments of the present application.

What is claimed is:

1. A method of manufacturing an array substrate, comprising:
providing a substrate;
forming a first metal layer, a buffer layer, and a semiconductor layer on the substrate sequentially, and patterning the first metal layer, the buffer layer, and the semiconductor layer, wherein the first metal layer forms a first electrode plate, a first light shielding portion, and a first metal portion, the buffer layer forms a first buffer portion, a second buffer portion, and a third buffer portion, the semiconductor layer forms a second electrode plate and an active portion, and wherein the first electrode plate, the first buffer portion and the second electrode plate are disposed correspondingly, the first light shielding portion, the second buffer portion, and the active portion are disposed correspondingly, and the third buffer portion is positioned at a side of the first metal portion away from the substrate; and
forming a second metal layer on a side of the semiconductor layer away from the substrate and patterning the second metal layer to form a third electrode plate, a drain electrode, a gate electrode, a source electrode, and a connecting portion, wherein the connecting portion is connected to the first metal portion.

2. The method of manufacturing the array substrate according to claim 1, wherein after the step of forming the first metal layer, the buffer layer, and the semiconductor layer on the substrate sequentially, and patterning the first metal layer, the buffer layer, and the semiconductor layer, the method further comprises:
forming a gate insulating layer covering the first metal layer, the buffer layer, and the semiconductor layer, and patterning the gate insulating layer to form a first opening, a second opening, a third opening, and a fourth opening, wherein the first opening and the second opening expose the active portion, the third opening exposes the first light shielding part, and the fourth opening exposes the first metal portion.

3. The method of manufacturing the array substrate according to claim 1, wherein after the step of forming the second metal layer on the side of the semiconductor layer away from the substrate, and patterning the second metal layer to form the third electrode plate, the drain electrode, the gate electrode, the source electrode, and the connecting portion, the method further comprises:
forming a first passivation layer covering the second metal layer and patterning the first passivation layer to form a first opening and a second opening, wherein the first opening exposes the source electrode, and the second opening exposes the connecting portion.

4. The method of manufacturing the array substrate according to claim 3, wherein after the step of forming the first passivation layer covering the second metal layer, and patterning the first passivation layer to form the first opening and the second opening, the method further comprises:
forming a protective layer in the second opening.

5. The method of manufacturing the array substrate according to claim 4, wherein after the step of forming the protective layer in the second opening, the method further comprises:
forming a second passivation layer and a second light shielding portion on a side of the first passivation layer away from the second metal layer sequentially.

6. The method of manufacturing the array substrate according to claim 5, wherein after the step of forming the second passivation layer and the second light shielding portion on the side of the first passivation layer away from the second metal layer sequentially, the method further comprises:
providing a light emitting diode in the first opening.

7. The method of manufacturing the array substrate according to claim 1, wherein the step of forming a first metal layer, a buffer layer, and a semiconductor layer on the substrate sequentially and patterning the first metal layer, the buffer layer, and the semiconductor layer comprises:
forming the first metal layer, the buffer layer, the semiconductor layer, and a photoresist layer on the substrate sequentially;
exposing the photoresist layer through a half-tone photomask or a grayscale photomask; and
patterning the first metal layer, the buffer layer, and the semiconductor layer.

8. An array substrate, wherein the array substrate is manufactured by a method of manufacturing the array substrate, and wherein the array substrate comprises:
a substrate;
a first metal layer, a buffer layer, and a semiconductor layer stacked on the substrate sequentially, wherein the first metal layer comprises a first electrode plate, a first light shielding portion, and a first metal portion, the buffer layer comprises a first buffer portion, a second buffer portion, and a third buffer portion, the semiconductor layer comprises a second electrode plate and an active portion, and wherein the first electrode plate, the first buffer portion, and the second electrode plate are disposed correspondingly, the first light shielding portion, the second buffer portion, and the active portion are disposed correspondingly, and the third buffer portion is positioned at a side of the first metal portion away from the substrate; and
a second metal layer provided on a side of the semiconductor layer away from the substrate, wherein the second metal layer comprises a third electrode plate, a drain electrode, a gate electrode, a source electrode, and a connecting portion, and wherein the connecting portion is connected to the first metal portion.

9. The array substrate according to claim 8, wherein the second metal layer is a three-layer structure of indium zinc oxide/molybdenum/copper or a double-layer structure of molybdenum oxide/copper.

10. The array substrate according to claim 9, wherein a thickness of the indium zinc oxide layer ranges from 15 nanometers to 30 nanometers, and a thickness of the molybdenum oxide layer ranges from 20 nanometers to 30 nanometers.

11. The array substrate according to claim 8, wherein the array substrate further comprises a first passivation layer covering the second metal layer, wherein the first passivation layer comprises a first opening and a second opening, the first opening exposes the source electrode, and the second opening exposes the connecting portion.

12. The array substrate according to claim 11, wherein a light emitting diode is provided in the first opening, wherein the light emitting diode is connected to the source electrode, a protective layer is provided in the second opening, and the protective layer covers the connecting portion.

13. The array substrate according to claim 8, wherein the array substrate further comprises a second passivation layer and a second light shielding portion, the second passivation layer is provided on a side of the first passivation layer away from the second metal layer, and the second light shielding portion is provided on a side of the second passivation layer away from the first passivation layer.

14. A display panel, comprising an array substrate, wherein the array substrate comprises:
a substrate;
a first metal layer, a buffer layer, and a semiconductor layer stacked on the substrate sequentially, wherein the first metal layer comprises a first electrode plate, a first light shielding portion, and a first metal portion, the buffer layer comprises a first buffer portion, a second buffer portion, and a third buffer portion, the semiconductor layer comprises a second electrode plate and an active portion, and wherein the first electrode plate, the first buffer portion, and the second electrode plate are disposed correspondingly, the first light shielding portion, the second buffer portion, and the active portion are disposed correspondingly, and the third buffer portion is positioned at a side of the first metal portion away from the substrate; and
a second metal layer formed on a side of the semiconductor layer away from the substrate, and the second metal layer comprises a third electrode plate, a drain electrode, a gate electrode, a source electrode, and a connecting portion, and wherein the connecting portion is connected to the first metal portion.

15. The display panel according to claim 14, wherein the second metal layer is a three-layer structure of indium zinc oxide/molybdenum/copper or a double-layer structure of molybdenum oxide/copper.

16. The display panel according to claim 15, wherein a thickness of the indium zinc oxide layer ranges from 15 nanometers to 30 nanometers, and a thickness of the molybdenum oxide layer ranges from 20 nanometers to 30 nanometers.

17. The display panel according to claim 14, wherein the array substrate further comprises a first passivation layer covering the second metal layer, and the first passivation layer comprises a first opening and a second opening, and wherein the first opening exposes the source electrode, and the second opening exposes the connecting portion.

18. The display panel according to claim 17, wherein a light emitting diode is provided in the first opening, wherein light emitting diode is connected to the source electrode, wherein a protective layer is provided in the second opening, and the protective layer covers the connecting portion.

19. The display panel according to claim 17, wherein the array substrate further comprises a second passivation layer and a second light shielding portion, the second passivation layer is provided on a side of the first passivation layer away from the second metal layer, and the second light shielding portion is provided on a side of the second passivation layer away from the first passivation layer.
